(19) United States
(12) Patent Application Publication
(10) Pub. No.: US 2012/0060899 A1
(43) Pub. Date: Mar. 15, 2012

(54) COLLECTOR FOR THE GENERATION OF ELECTRICAL AND THERMAL ENERGY

(76) Inventor: Joerg Helbig, Altenburg (DE)

(21) Appl. No.: 13/230,944

(22) Filed: Sep. 13, 2011

Related U.S. Application Data
(63) Continuation of application No. 12/595,176, filed on Oct. 8, 2009, now abandoned.

(30) Foreign Application Priority Data
Apr. 11, 2007 (DE) 10 2007 030 486.4

(51) Int. Cl. H01L 31/058; F24J 2/05

(52) U.S. Cl. 136/248; 126/652

(57) ABSTRACT

A solar collector with radiation opaque wafers for generating electrical and thermal energy from solar radiation includes a housing. A semitransparent photovoltaic module is disposed in the housing so as to form an upper part of the solar collector. A solar thermal module is disposed in the housing so as to form a lower part of the solar collector. The solar thermal module and the photovoltaic module form an insulation space therebetween, wherein the insulation space is configured to allow a heat radiation to pass while preventing a convective heat loss. A transparent support is disposed so as to close the collector in a direction of the solar radiation.

### CROSS REFERENCE TO PRIOR APPLICATIONS

This application is a continuation of U.S. application Ser. No. 12/595,176, filed Oct. 8, 2009, which is a U.S. National Phase Application under 35 U.S.C. §371 of International Application No. PCT/EP2008/002812, filed on Apr. 7, 2008, which claims benefit to German Application No. DE 10 2007 030 486.4, filed on Apr. 11, 2007. The entire disclosure of all applications is incorporated by reference herein.

### FIELD

The invention relates to a semitransparent collector which uses radiation opaque wafers for generating electrical and thermal energy from solar radiation energy.

### BACKGROUND

Solar thermal installations are understood to be technical systems for heating and industrial water using solar radiation energy. These generally comprise collectors, a connecting piping system, a heat carrier medium and a storage with heat exchangers for warm water. Additionally, there are measuring, control and actuating apparatuses.

The collectors form the core of such an installation. In principle, two types of collectors are available here.

Firstly, there is the vacuum tubes collector consisting of evacuated glass tubes. Within the tube there is a second tube or tube system which constitutes the actual absorber surface and through which the heat carrier medium flows. The inner tube is specially coated and lies at the focal points of laterally attached mirrors. This type of collector can supply very high temperatures and has a high efficiency. However, it is very expensive and not suited to being combined with photovoltaics for structural reasons.

The second type of collector is the so-called flat collector. This type consists of a specially coated aluminum or copper foil, at the rear side of which a preferably aluminum or copper tube system is mounted in a meandering or harp-like shape.

A glass plate or similar transparent materials cover the top of this collector for protection from environmental influences.

The radiation emitted by the sun can pass through this cover with almost no attenuation. A heat carrier medium flows through the piping system mounted below the absorber surface and thus transports the heat toward the storage system. A water-glycol mixture is usually used as a heat carrier medium to prevent frost damage.

Photovoltaics refer to the direct conversion of solar radiation into electrical energy due to the liberation of charge carriers in solids. To this end, the prior art uses semiconductors, i.e. substances which insulate near a temperature of absolute zero but become conductors at higher temperatures, due to targeted disturbance of the crystal lattice or due to the influx of external energy.

For photovoltaics to satisfy architectural needs such as visual appearance, thermal insulation, shadowing, aesthetics and glare protection, so-called semitransparent solar modules for integration into buildings (GIPV) have been available for quite some time. These are preferably thin layer cells, particularly amorphous, polycrystalline or CIS cells.

This affords the possibility of producing PV modules with a light transmission of 1% to 99%. In particular, this means that the photovoltaic proportion can be scaled freely.

Thus, there can be facades which absorb 90% of the light at certain locations but only absorb 10% elsewhere, in which, however, all modules have the same output voltage so that they can be connected in a conventional manner.

These semitransparent cells have a multiplicity of problems. For example the stability of the cells, during production and when the perforations are inserted into the wafers, is a particular risk factor which makes series production difficult.

The problems with semitransparent cells with wafers inserted between glass plates are rather of a visual nature.

This technology only lets light pass in small regions, with the remaining regions throwing large shadows due to the type of wafer used. The use of expensive silicon wafers and the large weight because two glass plates are used are further problems.

According to the prior art, solutions are proposed which combine the known photovoltaic components with those from solar thermal technology such that heat is transferred by thermal conduction, as a result of direct contact, from the heated wafers to the solar thermal module.

This creates disadvantages in respect of the tightness of the solar thermal module connected to the electrically conductive photovoltaic module and the feedback of heat conduction from the photovoltaic module to the absorber and vice versa during changing meteorological conditions.

Furthermore, it is disadvantageous that all materials used in the combined collector have different coefficients of thermal expansion and hence there can be mechanical problems in the system.

Furthermore, the direct connection of the solar thermal collector and the semitransparent PV module is connected with high thermal losses since the heat energy is emitted by direct contact from the solar thermal absorber to the PV cells and hence to the surroundings.

### SUMMARY

It is an aspect of the invention to solve problems in respect of the tightness and sealing the solar thermal collector from the photovoltaic elements in order to avoid short circuits, minimize thermal losses and rectify the disadvantages of the prior art. Furthermore, the drop in efficiency resulting from the combination of photovoltaics and solar thermal technology should be minimized and the mechanical problems should be resolved.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1 is a sectional drawing of the solar collector according to the invention;

FIG. 2 is a sectional drawing of the solar collector according to the invention; and

FIGS. 3-6 are embodiments of the solar collector according to the invention.

### DETAILED DESCRIPTION

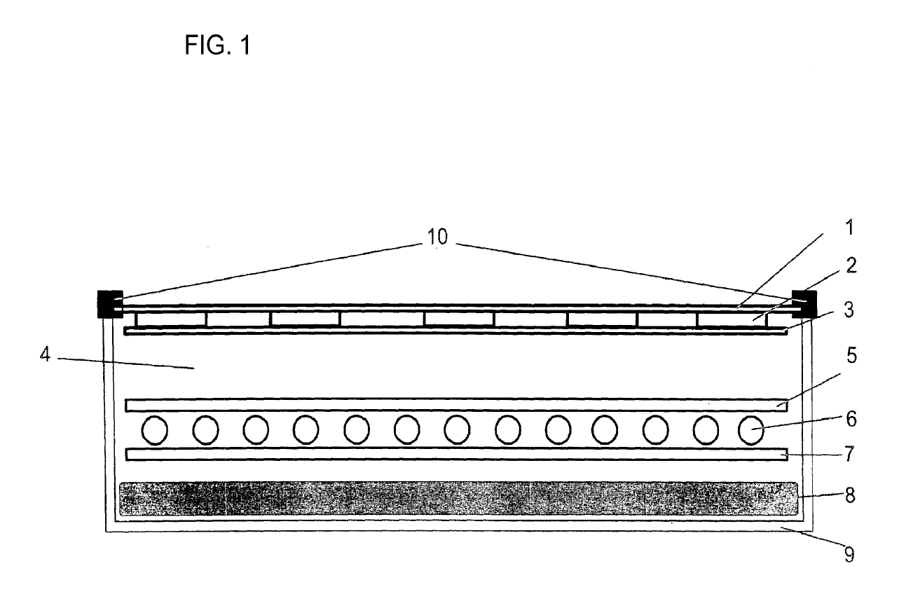

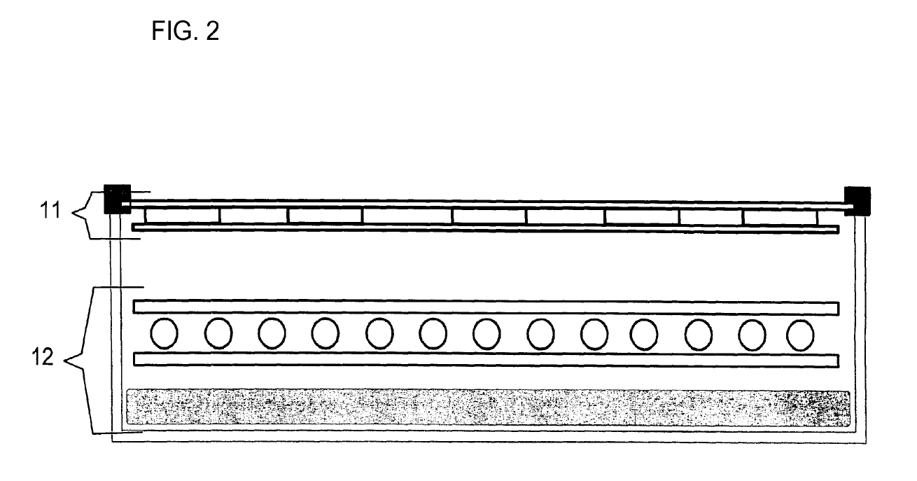

In the following text, the collector according to the invention is intended to be explained in more detail on the basis of FIGS. 1 and 2.

The collector according to the invention comprises a housing 9, which forms the base and the side walls of the collector and holds all additional components and parts of the collector, and a transparent support 1 which closes-off the collector toward the top and at the same time protects against external influences from this direction.

Alternatively, the solar thermal collector can be designed having a double-chamber profile with a vacuum or the interior of the housing as such can be evacuated.

The housing 9 and transparent support 1 are connected to each other using a seal 10 designed according to the prior art.

A semitransparent photovoltaic module 11 forms the upper part of the collector according to the invention, while the lower part of the collector corresponds to a solar thermal module 12.

Photovoltaic elements 2 are arranged on the underside and hence on the inner side of the transparent support 1, which photovoltaic elements are preferably affixed to the inner side of the transparent support 1 by means of a transparent fixing layer for PV elements 3.

In accordance with the prior art described, for example, in DE 4323270, these photovoltaic elements 2 are arranged with respect to the semitransparent hybrid collectors such that they only cover part of the irradiated surface and hence the sun can radiate into the collector.

According to the invention, an insulation space 4 is arranged below this fixing layer 3, the depth of which insulation space is designed according to the particular territorial requirements and/or was adapted to the degree of transmission of the semitransparent photovoltaic module 11.

The height of the insulation space 4 is determined by the degree of transparency. To this end, measurements have shown that it is advantageous to increase the height of the insulation space if the degree of transparency is increased because in this case the effect of the PV layer as a heat shield was detected in only a limited fashion. If the proportion of the photovoltaics increases, the degree of transparency decreases. In this case it is advantageous to reduce the distance since the PV layer formed from radiation opaque wafers acts as a heat shield and additionally the heated photovoltaic cells transfer heat by means of heat radiation more easily to the absorber layer when the distance is reduced.

The insulation space 4 is adjoined by an absorber 5 which preferably has a coating which improves the effectiveness thereof, piping 6 for the medium carrying the heat energy, a reflection layer 7 and insulation 8 arranged below said layer.

Likewise, the reflection layer 7 can be arranged as an absorption layer and the insulation 8 obtains a reflection layer.

The photovoltaic elements 2 emit heat energy into the interior of the collector because the outer semitransparent photovoltaic component forms a heat shield preventing heat emission to the surroundings due to a higher temperature potential thereof compared to the solar thermal absorber.

Thermalization is a loss mechanism which results in extreme heating of the cells. Heating by the infrared component of the sunlight generates so-called lattice oscillations. These in turn ensure that photons not involved in the charge separation process are more likely to collide with the lattice structure. These photons having energy greater than the band gap excite the charge carriers into states which lie above the band edge. The difference between the energy of the excited state and the energy of the band edge is transferred to the crystal lattice as thermal energy.

During operation the photovoltaic component thus has a higher temperature compared to the absorber 5 and this prevents heat loss in this direction.

The insulation space 4 which prevents convective heat losses but transmits heat radiation defines the distance of the photovoltaic component to the solar thermal component which is arranged below the insulation space 4 in the installation direction.

If the height of the insulation space 4 is maximized, the electrical efficiency of the photovoltaic component is increased because less heat energy is transferred from the solar thermal absorber 5 to the semitransparent PV module 2.

If the height of the insulation space 4 is minimized, this increases the heat transfer from the solar thermal component 5 to the photovoltaic component 2 and the electrical efficiency is minimized since the operation of photovoltaic elements is lossy above standard test conditions with a cell temperature of 25° C.

Thus, selecting the height of the insulation space 4 affords the possibility of adjusting the collector according to the invention in accordance with the respective requirements.

Depending on the respective requirement, an adjustment can be effected according to the respective requirement for electrical energy and heat energy.

This is effected by selecting the distance between the solar thermal absorber 5 and the photovoltaic module 2; a further possibility for adjusting comprises selecting the degree of transparency of the photovoltaic module 2.

The possibility of no transparent fixing layer 3 should also be considered to be within the scope of protection if the photovoltaic layer 2 is attached to the transparent support 1 in a different fashion.

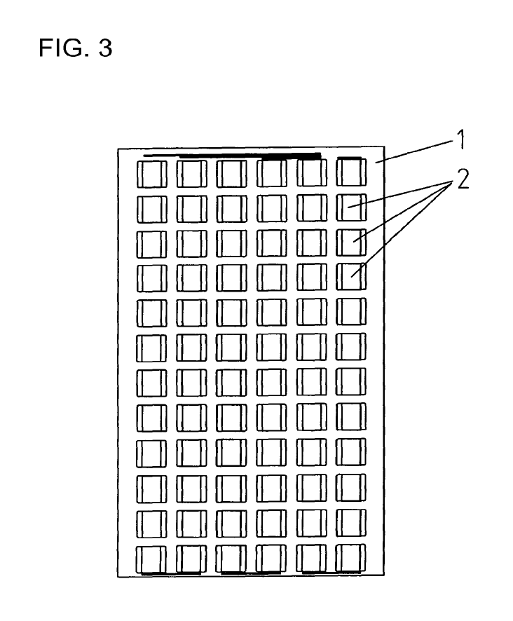

In the following text, the solution according to the invention is intended to be explained in more detail on the basis of exemplary embodiments and FIGS. 3 to 6.

One exemplary embodiment of the invention is illustrated in FIG. 3. By way of example, shown here is the case where the proportion of the total surface which is transparent is 60%. This is achieved by the evenly distributed arrangement of silicon wafers or by extensive cutting of thin layer solar cells which are subsequently subdivided into many individual photovoltaic regions by suitable methods.

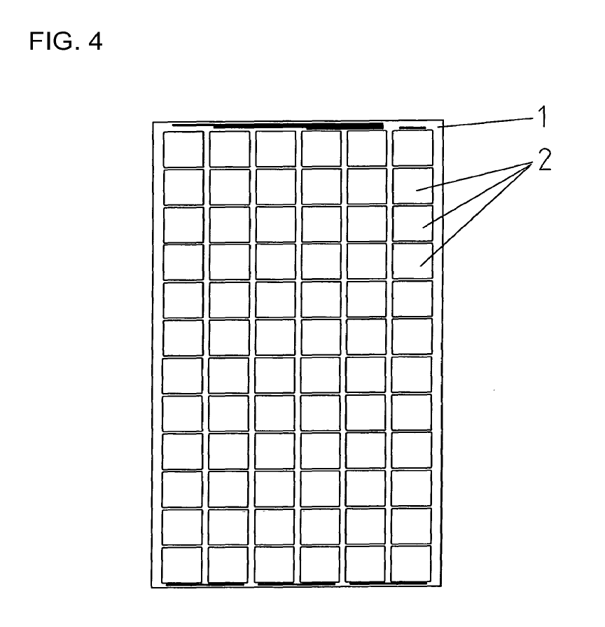

The degree of transparency can advantageously be scaled freely in the case of thin layer technology, whereas the degree of transparency when using silicon wafers is determined by the size of the wafers used. Thus, as shown in FIG. 3, the use of 5 inch wafers can achieve a degree of transparency of 60%, whereas 6 inch wafers achieve a degree of transparency of 30%, as shown in FIG. 4.

The degree of transmission can also be set by a local photovoltaic section and a transparent section. An advantageous interpretation of the solution according to the invention can for example consist of a concentrated arrangement of the photovoltaic part in part of the collector.

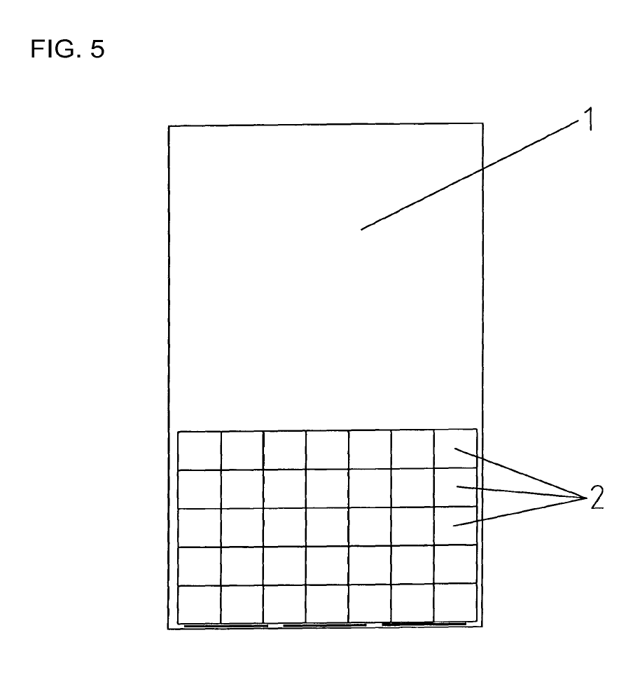

In this case it would in turn be advantageous to arrange the photovoltaic part at the bottom, as shown in FIG. 5. Here, a positive effect would be a lower thermal load on the photovoltaic cells at rest or when little heat is removed, since a solar thermal collector develops the least amount of heat at that location due to the design thereof. By contrast, an opposing flow can also be selected, as a result of which a different distribution of the photovoltaic elements becomes possible.

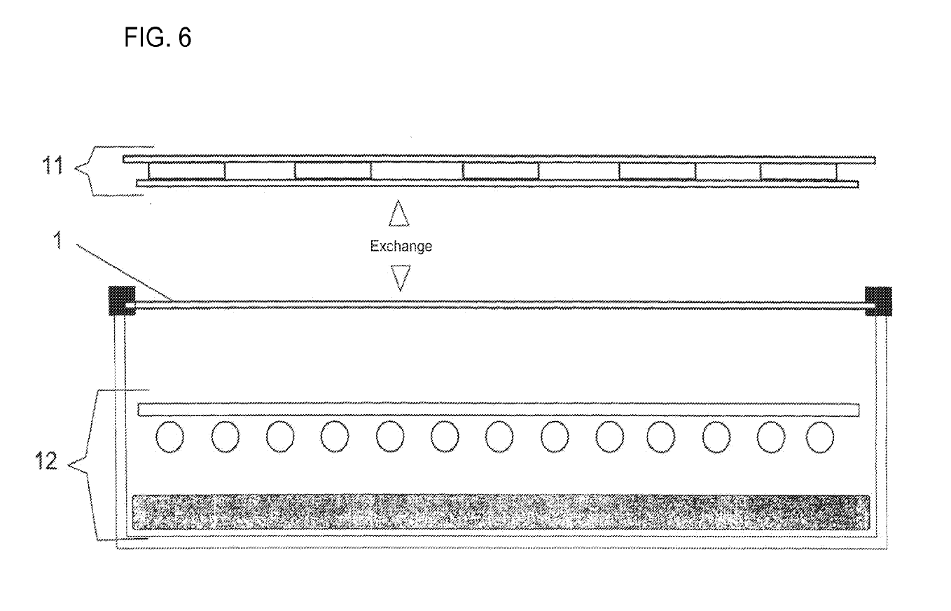

FIG. 6 shows a solar thermal collector corresponding to the prior art. It is altered by replacing the transparent layer 1 with a corresponding semitransparent photovoltaic support layer. This affords the possibility of retrofitting already installed solar thermal collectors such that a collector in accordance with the solution according to the invention is created.

While the invention has been described with reference to particular embodiments thereof, it will be understood by those having ordinary skill the art that various changes may be made therein without departing from the scope and spirit of the invention. Further, the present invention is not limited to the embodiments described herein; reference should be had to the appended claims.

1-11. (canceled)

12. A solar collector with radiation opaque wafers for generating electrical and thermal energy from solar radiation, the solar collector comprising:
a housing;
a semitransparent photovoltaic module disposed in the housing so as to form an upper part of the solar collector;
a solar thermal module disposed in the housing so as to form a lower part of the solar collector, the solar thermal module and the photovoltaic module forming an insulation space therebetween, wherein the insulation space is configured to allow a heat radiation to pass while preventing a convective heat loss; and
a transparent support disposed so as to close the collector in a direction of the solar radiation.

13. The solar collector as recited in claim 12, wherein the photovoltaic module includes photovoltaic elements disposed on an underside of the transparent support such that the photovoltaic elements are disposed on an inner side of the photovoltaic module.

14. The solar collector as recited in claim 12, wherein the solar thermal module includes an absorber, a piping for a heat energy carrying medium, a reflection layer and an insulation disposed below the reflection layer.

15. The solar collector as recited in claim 12, wherein a depth of the insulation space is based on at least one of a particular territorial requirement and a specific meteorological condition.

16. The solar collector as recited in claim 13, wherein a depth of the insulation space is selected based on a degree of transmission of the photovoltaic elements.

17. The solar collector as recited in claim 16, wherein a depth of the insulation space is selected based on at least one of a particular territorial requirement and a specific meteorological condition.

18. The solar collector as recited in claim 12, wherein the photovoltaic module includes a plurality of solar cells disposed at a distance from one another such that the photovoltaic module is transparent.

19. The solar collector as recited in claim 18, wherein the solar thermal module includes an absorber without a coating such that a radiation energy of the plurality of solar cells is absorbed by a photovoltaic element of the photovoltaic module.

20. The solar collector as recited in claim 14, wherein the reflection layer is an absorption layer and the insulation includes an insulation reflection layer.

21. The solar collector as recited in claim 12, wherein the collector includes a local photovoltaic section and a transparent section.

22. A solar collector with radiation opaque wafers for generating electrical and thermal energy from solar radiation, the solar collector comprising:
a housing;
a semitransparent photovoltaic module disposed in the housing so as to form an upper part of the solar collector and including a transparent support disposed so as to close the collector in a direction of the solar radiation; and
a solar thermal module disposed in the housing so as to form a lower part of the solar collector, the solar thermal module and the photovoltaic module forming an insulation space therebetween, wherein the insulation space is configured to allow a heat radiation to pass while preventing a convective heat loss.
